(19) United States
(12) Patent Application Publication
(10) Pub. No.: US 2026/0039002 A1
(43) Pub. Date: Feb. 5, 2026

(54) POWER DIVIDER

(71) Applicant: Marki Microwave, Inc., Morgan Hill, CA (US)

(72) Inventors: Christopher Ferenc Marki, Morgan Hill, CA (US); Jeff Luu, Morgan Hill, CA (US); Thaibao Quoc Phan, Morgan Hill, CA (US)

(21) Appl. No.: 19/183,614

(22) Filed: Apr. 18, 2025

Related U.S. Application Data
(60) Provisional application No. 63/677,221, filed on Jul. 30, 2024.

(51) Int. Cl. H01P 5/12; H01Q 3/36; H03H 7/38

(52) U.S. Cl. CPC H01P 5/12; H01Q 3/36; H03H 7/38

(57) ABSTRACT

A radio frequency (RF) power divider includes an input port, an internal node, and two output ports. The RF power divider also includes a lumped element divider circuit that links the internal node to the two output ports. This divider circuit includes two branch circuits, each including an inductor that connects the internal node to one of the output ports. Additionally, the RF power divider further includes an isolation circuit positioned between the two output ports, which includes a resistor. An impedance matching circuit connects the input port to the internal node. This impedance matching circuit is configured to selectively transmit or dissipate signal energy within a predetermined frequency band received from the input port, ensuring efficient power transfer and reduced signal reflection.

### CROSS REFERENCE TO RELATED APPLICATION

This application claims priority to U.S. Provisional Patent Application Ser. No. 63/677,221, filed on Jul. 30, 2024, which is incorporated herein by reference in its entirety.

### BACKGROUND

A power divider is an electronic circuit or device used to split an input signal into two or more output signals, distributing the power equally or proportionally among the output ports. Power dividers may be used in radio frequency (RF) and microwave systems, such as communication systems, radar, and antennas, where signals need to be split or combined without significantly affecting the signal's integrity.

For example, power dividers may be used in phased array antenna, which is a type of antenna system that uses multiple individual antenna elements arranged in an array, where the relative phase of each element's signal is electronically controlled to steer the direction of the radio wave beam without physically moving the antenna. By adjusting the phase of the signal at each element, the antenna can direct its radiation pattern in specific directions, either for transmission or reception. In a phased array antenna, a power divider divides a single input signal into multiple signals, which are fed to multiple antenna elements.

Traditional power dividers, such as the Wilkinson power divider, cover a broad range of frequencies, including DC. This results in suboptimal performance and larger circuit size. However, in applications like phased-array systems, space limitations often require components to be minimized in physical size. Traditional power dividers are typically too large to meet these constraints.

### SUMMARY

Embodiments described herein relate to a radio frequency (RF) power divider. The RF power divider includes an input port, an internal node, two output ports, a lumped element divider circuit, and an impedance matching circuit. The internal node can be resistively terminated to provide isolation across the output ports. The power divider may be realized using different configurations, including a lumped element divider circuit, distributed transmission line elements, or a combination of both. In some embodiments, a lumped element divider circuit connects the internal node to the two output ports, forming two branch circuits. Each of the two branch circuits includes an inductor connecting the internal node to one of the two output ports, and an isolation circuit between the two output ports. In some embodiments, each branch circuit is a lumped element equivalent of a quarter-wave transmission line between the internal node and one of the output ports. The isolation circuit includes a resistor. The impedance matching circuit connects the input port to the internal node. The impedance matching circuit is configured to selectively transmit or dissipate signal energy within a predetermined frequency band received from the input port.

In some embodiments, the isolation circuit further includes a capacitor in series with the resistor, forming a series R-C (resistor-capacitor) circuit between the two output ports. In some embodiments, the isolation circuit further includes a second resistor connected in parallel with the series R-C circuit between the two output ports.

In some embodiments, the impedance matching circuit includes a capacitor connecting the input port to the internal node, and a shunt inductor connecting the input port to ground.

In some embodiments, the lumped element divider circuit further includes capacitors connecting the internal node to grounds, and connecting each of the two output ports to ground. In some embodiments, the lumped element divider circuit is a Wilkinson power divider. In some embodiments, the input port and output ports are all matched to a same characteristic impedance, but an input impedance of the lumped element divider circuit is not matched to the characteristic impedance.

Embodiments described herein also relate to an RF power divider, including a first node, two output ports, and a divider circuit connecting the first node to the two output ports. The divider circuit includes two branch circuits and an isolation circuit between the two output ports. Each branch circuit includes an inductor in series with a quarter-wave transmission line, and the isolation circuit includes a resistor.

Embodiments described herein also relate to an RF system, including one or more stages, each stage including one or more RF power dividers described above.

Embodiments described herein also relate to a phased-array system, including an RF source that generates an RF source signal, an RF system described above, multiple phase-shifting components coupled to the output ports of a last stage of the RF system, and multiple antenna elements coupled to the phase-shifting components. The RF system splits the RF source signal into multiple lower power RF signals. The phase-shifting components are controllable to phase shift the multiple lower power RF signals.

Other aspects include components, devices, systems, improvements, methods, processes, applications, and other technologies related to any of the above.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1A illustrates an example circuit of a radio frequency (RF) power divider, in accordance with some embodiments.

FIG. 1B illustrates another example an RF power divider circuit, in accordance with one or more embodiments.

FIG. 1C illustrates yet another example of an RF power divider circuit, in accordance with some embodiments.

FIG. 2 illustrates another example of an RF power divider circuit, in accordance with some embodiments.

FIG. 3 illustrates an example of a 4:1 (2-stage) power divider circuit, in accordance with some embodiments.

FIG. 4 illustrates an example 8:1 (3-stage) power divider circuit in accordance with one or more embodiments.

FIG. 5 illustrates an example phased-array system in accordance with one or more embodiments.

### DETAILED DESCRIPTION

Aspects of the present disclosure relate to a radio frequency (RF) power divider. A power divider (also referred to as a power splitter) is an electronic circuit or device used to split an input signal into two or more output signals, distributing the power equally or proportionally among the output ports. Such a device also has a reciprocal nature, such that the device can function both as a power divider and a power combiner depending on how the input and output ports are used.

Traditional power dividers, such as the Wilkinson power divider, cover a broad range of frequencies, including DC, which is often unnecessary for specific applications. This results in suboptimal performance, such as increased insertion loss, lower isolation, and larger in physical size. Increased insertion loss means a significant amount of power is lost during operation as heat or inefficiencies rather than being delivered to the output. Isolation refers to the ability of the power divider to minimize signal leakage between output ports.

The embodiments described herein enable the optimization of power dividers for a specific frequency band, improving performance within that band, including reducing insertion loss, increasing isolation, reducing reflections, and decreasing the device footprint.

In some embodiments, a power divider described herein includes an impedance matching circuit between the input port and the divider circuit to provide impedance matching for higher-frequency signals without increasing inductor size in the divider circuit, thereby achieving a compact footprint for high-frequency applications. Alternatively, or additionally, the power divider includes an RC isolation circuit between adjacent output ports to improve isolation for low-frequency signals without the requirement of extending quarter-wave sections in the divider circuit, thereby achieving a compact footprint for low-frequency applications.

Power dividers described herein can be constructed using a variety of materials that are suitable for RF signal transmission. These materials can be selected based on their ability to work effectively at radio frequencies (RFs). In some embodiments, the signals handled by the device may cover a wide frequency range, from DC (0 Hz) up through microwave frequencies (300 MHz to 300 GHz), and even beyond, including higher and lower frequencies or combinations thereof.

In some embodiments, a power divider may be constructed as part of a monolithic microwave integrated circuit (MMIC). This means the material and design topology are suitable for integration into a microwave circuit, which can operate across different frequency ranges. An MMIC is fabricated by patterning a single piece of material, such as gold on gallium arsenide (GaAs) or copper on silicon. The MMIC construction does not limit the device to only one or more microwave frequency ranges. Instead, it may allow for flexibility in the choice of materials used in the physical construction of the device.

In some embodiments, the connections within the power divider are made using electrical connections that ensure the proper flow of electrical energy and signal power through the device. Connection materials can be any suitable conductive material, such as a metallic electrical conductor. These materials may be homogeneous (of a signal material type) or heterogeneous (a combination of different materials). The materials may also be combined, coated, or plated to enhance performance or reliability.

The specific embodiment and parameter values of a power divider are determined based on the target input frequency range, input signal impedance, and the application in which the power divider is to be implemented. The target input frequency ranges may include (but are not limited to) very high frequency (30 MHz to 300 MHz), ultra-high frequency (300 MHz to 3 GHZ), L-Band and S-Band (1 GHz to 4 GHZ), C-Band (4 GHz to 8 GHZ), X-Band (8 GHz to 12 GHz), Ku-Band (12 GHz to 18 GHz), K-Band and Ka-Band (18 GHz to 40 GHz), and Millimeter Wave and beyond (30 GHz to 300 GHz).

### Non-Distributed Power Divider

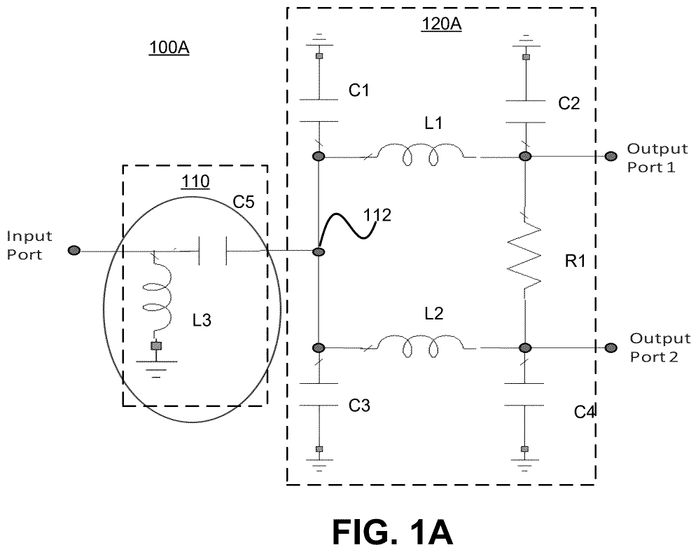

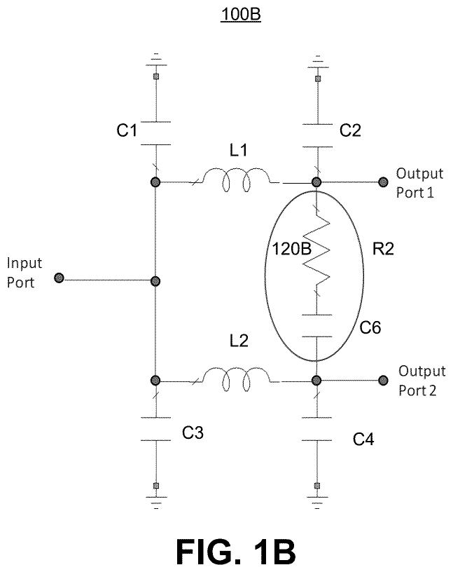

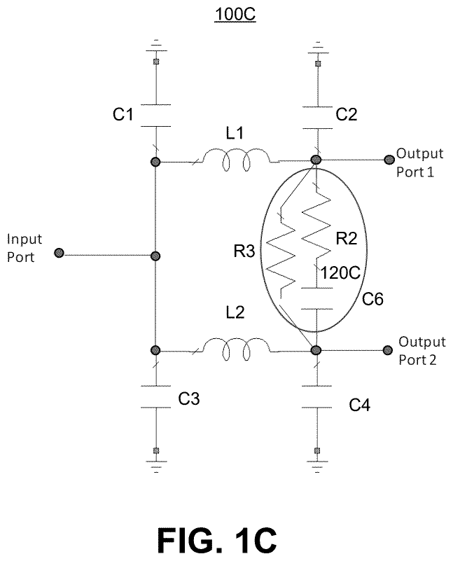

FIG. 1A illustrates an example circuit of an RF power divider, in accordance with some embodiments. The power divider 100A includes an input port, internal node 112, two output ports (namely, output port 1 and output port 2), a lumped element divider circuit 120A, and an impedance matching circuit 110. The lumped element divider circuit 120A connects the internal node 112 to the two output ports.

The divider circuit 120A includes two branch circuits, each including an inductor connecting the internal node 112 to one of the two output ports. As illustrated, a first branch circuit includes inductor L1 connecting the internal node 112 to output port 1; a second branch circuit includes inductor L2 connecting the internal node 112 to output port 2. The impedance matching circuit 110 connects the input port to the internal node 112. The impedance matching circuit 110 matches an input impedance of the lumped element divider circuit 120A to a source impedance for the input port. In some embodiments, each branch circuit is a lumped element equivalent of a quarter-wave transmission line between the internal node and one of the output ports.

The input port receives an RF signal, which may be a signal source, such as a transmitter or a signal generator. The signal enters the input port is often at a specific impedance (e.g., 50 ohms), and the impedance matching circuit 110 is configured to match the impedance of the input port (also referred to as “source impedance” or “impedance of the input”) to the divider circuit 120A to minimize signal loss or reflection. In particular, the impedance matching circuit 110 is configured to selectively transmit or dissipate signal energy within a predetermined frequency band received from the input port. As illustrated, in some embodiments, the impedance matching circuit 110 is an LC (inductor-capacitor) circuit, may be configured to tune the impedance of the circuit for a specific frequency range. The LC circuit includes a capacitor C5 (also referred to as a series capacitor) connected in series to the divider circuit 120A, and an inductor L3 (also referred to as a shunt inductor) connected in parallel to the capacitor C5 and the divider circuit 120A.

The inductance of each of the inductors L1 and L2 is determined based on the capacitance of the series capacitor C5 and the shunt inductor L3. When the power divider 100A includes the impedance circuit 110, the inductance of L1 and L2 can be significantly reduced while achieving similar performance compared to a traditional power divider without the impedance matching circuit 110, thereby resulting in a much smaller footprint for the power divider 100A.

In some embodiments, the impedance matching circuit 110 is configured to block or filter out low-frequency signals, including DC signals, such that the power divider 100A is configured to operate within a specific frequency band, and it is not required to handle signals that are low or zero frequency (e.g., DC or extremely low frequency). This allows the power divider 100A to focus its performance on higher frequencies, where it can be more efficient and compact.

The divider circuit 120A is configured to divide the input signal into two output. The output ports 1 and 2 output signals that have been divided by the divider circuit 110A. In some embodiments, the input signal is divided equally between the two output ports, meaning that each output port 1 or 2 will output half the power of the input signal.

The resistor R1 is an isolation resistor configured to ensure isolation between output port 1 and output port 2, thereby reducing the impact of reflections or mismatches at one output port on the signal at the other output port. Inductors L1-L2 and capacitors C1-C4 are configured to form a filtering network. Capacitors C1-C4 are connected to ground. Based on the parameters set for inductors L1-L3 and capacitors C1-C4, the divider circuit 120A may be configured to operate more effectively within a specific frequency range by allowing signals in the specific frequency range (e.g., frequency greater than a threshold) to pass through while blocking the remaining frequency (e.g., low frequency) signals.

FIG. 1B illustrates another example a power divider 100B, in accordance with one or more embodiments. As illustrated, power divider 100B includes an input port and two output ports (output port 1 and output port 2). The power divider 100B also includes two branch circuit, each including an inductor in series with a quarter-wave transmission line. In particular, a first branch circuit includes inductor L1, and a second branch circuit includes inductor L2.

Unlike the power divider 100A, the power divider 100B may or may not include the impedance matching circuit 110. Further, unlike the power divider 100A, which uses a resistor R1 to isolate between the two output ports, the power divider 100B includes an isolation circuit 120B, including a series RC (resistor-capacitor) network. As illustrated, the RC network includes resistor R2 and capacitor C6. The capacitor C6 introduces zeros into the frequency response of the isolation, where “zeros” refer to specific frequencies at which isolation is nearly perfect.

The R-C network 120B improves the isolation characteristics, particularly in terms of frequency response. By adding a capacitor C6 to the isolation network, the power divider 100B introduces poles (i.e., specific frequencies) into the frequency response of the isolation. These poles help to improve isolation performance at certain frequencies.

In some embodiments, the R-C isolation circuit 120B is tuned to improve isolation between the output ports at specific frequencies (especially low frequencies) without (or with little) effect over the splitter's performance metrics related to insertion loss and return loss. Insertion loss refers to an amount of signal power lost when the signal passes through the power divider 100B. The lower the insertion loss, the more efficient the divider 100B is at transmitting the signal to the output ports. Return loss refers to how much of the signal is reflected back toward the source due to impedance mismatches. Higher return loss indicates less reflection and better impedance matching. Those characteristics may also depend on the other components and parameter values of those components, such as the impedance circuit 110 and L1, L2, C1-C4.

Further, the power divider 100B enhances isolation over a wider range of lower frequencies without the need to increase the physical dimensions of the circuit. A quarter-wave section refers to the length of quarter-wave sections in the circuit that are a quarter of the wavelength of the operating frequency. Traditionally, improving isolation over a broader range of lower frequencies requires lengthening the quarter-wave section in the power divider or increasing the size of the LC pairs (L1-L2, and C1-C4), leading to larger physical dimensions of the circuit. In contrast, the RC network 120B described herein enables enhanced isolation over a wider range of lower frequencies without the need to extend the quarter-wave section or enlarge the LC pairs (L1-L2, and C1-C4) in the power divider 100B.

FIG. 1C illustrates yet another example of a power divider 100C, in accordance with some embodiments. Again, in some embodiments, the power divider 100C may include an impedance matching circuit 110. This embodiment is similar to that illustrated in FIG. 1B, except that the isolation network includes both resistors R2 and R3 and capacitor C6. R2, R3 and C6 work together to ensure isolation between Output Port 1 and Output Port 2. Capacitor C6 also plays a role in stabilizing the circuit within its frequency range.

Similar to power dividers 100A, 100B, the overall function of power divider 100C (including isolation) is optimized for operation within a specific frequency range, which is controlled by the values of inductors L1-L2 and capacitors C1-C4 and C6.

### Distributed Power Divider

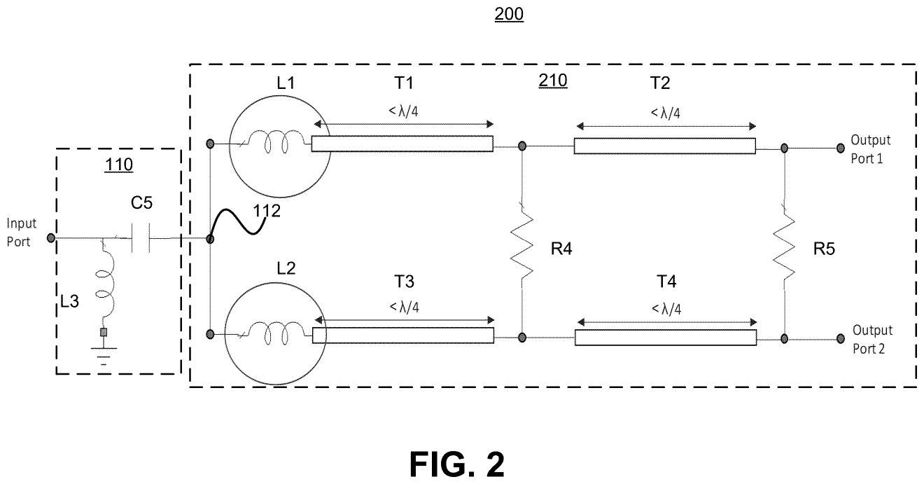

FIG. 2 illustrates another example of a power divider 200, in accordance with some embodiments. The power divider 200 is an improved distributed power divider. Unlike non-distributed power dividers, the distributed power divider 200 use transmission line elements (e.g., quarter-wavelength sections) to provide impedance matching over specific frequency range.

As illustrated, the power divider 200 includes an input port, an internal node 112, two output ports (Output Port 1 and Output Port 2), an impedance matching circuit 110, a divider circuit 210. As illustrated, the divider circuit 210 includes two branch circuits, each including an inductor in series with a quarter-wave transmission line. In particular, a first branch circuit includes inductor L1 and transmission lines T1 and T2; and a second branch circuit includes inductor L2 and transmission lines T3 and T4. The power divider 200 also includes an isolation circuit including a resistor R5 between the two output ports. In some embodiments, the isolation circuit further includes another resistor R4 connected to all four transmission lines.

A quarter-wave section T1, T2, T3, or T4 is a transmission line or waveguide that has a physical length equal to one-quarter of a wavelength (λ/4) of the signal it is configured to carry. For example, when the target RF frequency is 10 GHz, λ/4 is about 7.5 mm. The impedance matching circuit 110 is configured to provide impedance matching between the input signal and the power divider 200.

The input port receives an RF signal, which may originate from a transmitter or signal generator. Inductors L1 and L2 are placed in series with the input signal and form part of filtering network. The inductor L1 or L2 is a discrete series inductor. As such, the inductor L1 or L2 is a separate component (not distributed along a line), and it is placed in series with the circuit. By adding the series inductor L1 or L2, the input impedance is adjusted to better match the ideal value in a traditional power divider. These inductors work in conjunction with quarter-wave sections T1-T4 to ensures proper impedance transformation and allows for efficient splitting of the input signal. The quarter-wave sections T1, T2, and T3, T4 are connected in series to achieve certain impedance. Each quarter-wave section T1-T4 acts as an impedance transformer. When the input impedance doesn't directly match the desired output impedance, cascading multiple quarter-wave sections can achieve a gradual impedance transformation, reducing reflection losses.

Traditionally, increasing impedance requires increasing the number of the quarter-wave sections T1-T4 and/or thickening the substrate on which the circuit is built, resulting in a larger device footprint. In contrast, the power divider 200 described herein utilizes discrete inductors L1 and L2 connected in series with the quarter-wave sections T1-T4, enabling a significantly smaller footprint for the power divider 200.

Resistors R4 and R5 are isolation resistors, positioned between the two branches of the circuit, reducing mismatches or reflections between the end of quarter-wave sections T1/T3 and T2/T4.

The values of inductors L1 and L2, quarter-wave sections T1 through T4, and resistors R4 and R5 are determined based on a target frequency range, input signal impedance, parameters of the impedance matching circuit 110 and other parameters associated with specific applications.

In some embodiments, the isolation resistor R4 or R5 in the power divider 200 may be replaced with the isolation circuit 120B in FIG. 1B or isolation circuit 120C in FIG. 1C. In some embodiments, the power divider 200 may not include the impedance matching circuit 110, depending on the target input frequency and the requirements of the application.

### Multi-Stage Rf Power Divider

In some embodiments, multiple power dividers 100A, 100B, or 100C may be combined together to form a multi-stage power divider configured to divide an input signal into 4 output signals, 8 output signals or even more.

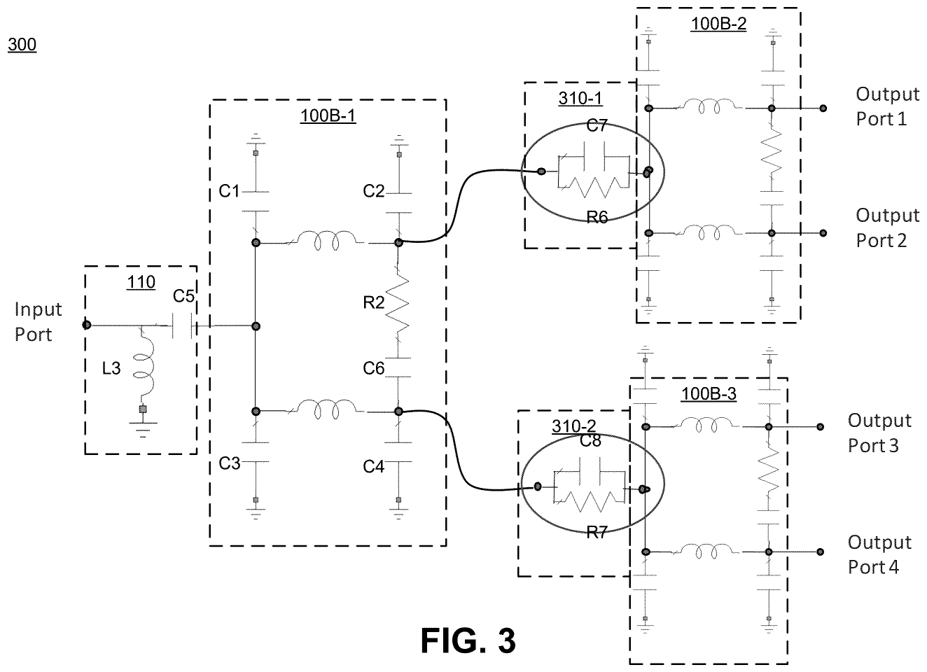

FIG. 3 illustrates an example of a 4:1 (2-stage) power divider 300, in accordance with some embodiments. The circuit includes an input port, which connects to multiple output ports (namely output port 1-4). Between the input port and output ports, there are a first impedance matching circuit 110, multiple instances of power divider 100B from FIG. 1B and multiple second instances of impedance matching circuit 310.

The 4:1 power divider circuit includes two stages. The first stage includes a first power divider circuit 110B-1, the second stage includes to two impedance matching circuits 310-1 and 310-2 and two power divider circuits 110B-2, 110B-3. The first power divider circuit 110B-1 is configured to receive an input signal and divide the input signal into two ½ signals. The two outputs of the first power divider circuit 110B (i.e., two ½ signals) are then input to the two impedance matching circuits 310-1, 310-2, the output of which is then fed into the two power divider circuits 310B-2, 310B-3 in the second stage. Each of the two power divider circuits 310B-2, 310B-3 is configured to divide a corresponding ½ signal into two ¼ signals. As such, each of the output port 1-4 outputs a ¼ signal corresponding to ¼ power of the original input signal received from the input port.

In the embodiments shown in FIG. 3, the impedance matching circuit 310-1, 310-2 includes a parallel R-C (resistor-capacitor). Further, the isolation is achieved by a series R-C network (including resistor R2 and capacitor C6). The impedance matching and isolation matching based on R-C networks enables the shifting of the isolation response to a lower frequency while maintaining a compact form factor.

Note, although power divider 300 is shown including multiple power dividers 100B, this is just one example. Other circuits, such as power divider 100A, 100C, or 200 can also be implemented at any or all stages of power divider 300, depending on the target range of the input signal, the impedance of the input, and the specification of application.

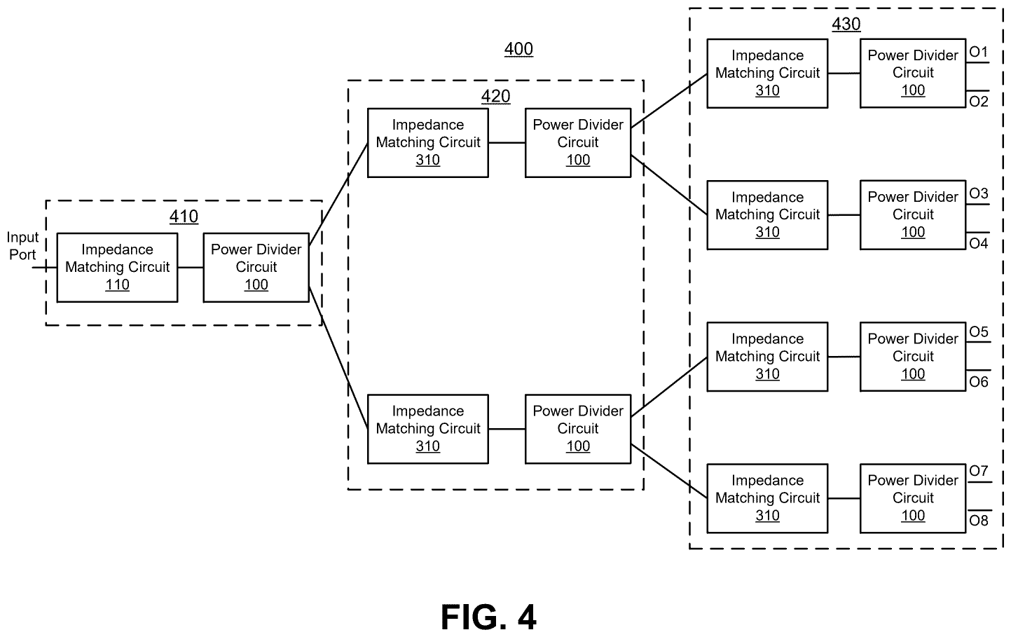

FIG. 4 illustrates an example 8:1 (3-stage) power divider circuit in accordance with one or more embodiments. The power divider 400 includes an input port and multiple output ports (O1 through O8). Between the input and output ports, the circuit includes three stages 410, 420, 430. The outputs of the first stage 410 feed to the second stage 420; the outputs of the second stage 420 feed to the third stage 430. Each stage includes one or more impedance matching circuit 110, 310 and one or more power divider circuit 110, which may be any one of power divider 100A, 100B, 100C, or 200.

The input port receives an RF signal, and feeds it into the first stage 410, which includes an impedance matching circuit 110 and a power divider 100. The impedance matching circuit in the first stage 410 is configured to cause the impedance of the incoming signal to match the impedance of the circuit in the first stage 410, ensuring minimal signal loss and reflection before passing the signal to the second stage 420.

The second stage includes a pair of impedance matching circuit 310 and power divider 100, each receives ½ power signal generated by the first stage via dividing the original input signal. Again, each impedance matching circuit 310 in the second stage is configured to cause the impedance of the incoming signal (i.e., ½ power signal) to match the impedance of the circuit in the second stage 420. Each power divider circuit 110 in the second stage is configured to divide the ½ power signal into half (i.e., ¼ power signal) and output from their output ports.

The third stage includes two pairs of impedance matching circuit 310 and power divider circuit 110, each receives ¼ power signal generated by the second stage via dividing the ½ power signal. Again, each impedance matching circuit 310 in the third stage is configured to cause the impedance of the incoming signal (i.e., ¼ power signal) to match the impedance of the circuit in the third stage 430. The power divider circuit 110 in the third stage 430 is configured to divide the ¼ power signal into half (i.e., ⅛ power signal) and output from their output ports 1-8.

Note, FIG. 4 is just one example of a 3-stage power divider circuit. The same principles can be extended to power divider circuits with more stages. Additionally, the embodiments described here show that all output ports can be configured to deliver equal fractions of the original signal's power, though this is not always required. In certain applications, the outputs may be configured to deliver different portions of the signal's power. As illustrated, except for a last stage, output ports of each stage are connected to input ports of a next stage.

### Example Use Case-Phased-Array System

The power dividers described herein can be integrated in a wide range of applications, such as in RF and microwave systems. Such applications include (but are not limited to) antenna systems, radar systems, telecommunication systems, measurement and testing equipment, signal processing, and/or satellite communication systems. In a phased-array systems, power dividers may be used to split a signal across multiple antenna elements. In radar systems, power dividers may be used to distribute the transmitted radar signal to multiple antennas or radar elements. In telecommunications systems, power dividers may be used in base stations (e.g., 4G and 5G) to split signals among different antennas to cover multiple sectors or directions. Further, power dividers may also be used in RF testing equipment to allow simultaneous measurement of signals. Additionally, power dividers may also be used in amplifier systems where a signal needs to be distributed across multiple amplifiers for processing and then recombined for transmission.

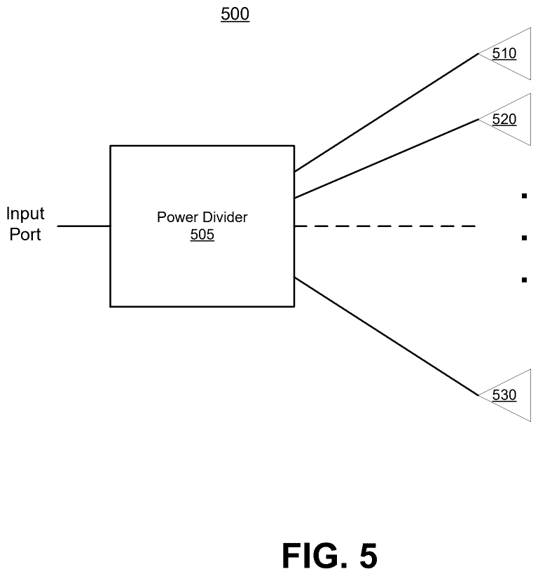

FIG. 5 illustrates an example phased-array system 500 in accordance with one or more embodiments. The phased-array system 500 includes a power divider 505 and multiple antenna elements 510-530. The power divider 505 may correspond to a power divider 100A, 100B, 100C, 200, 300, or 400. The power divider 505 includes an input port configured to receive an RF signal and output multiple divided RF signals, each of which is input to an antenna element 510-530. Each of the antenna element 510-530 is configured to convert the received divided RF signal (lower power RF signal) into electromagnetic wave and radiates it into space.

In some embodiments, between the output port of the power divider 505 and each antenna element 510-530, there is a phase-shifting component (not shown) coupled to the output ports of a last stage of the RF system. The phase-shifting component is controllable to phase shift the multiple lower power RF signals. For instance, the phase-shifting component may be configured to change a phase angle of an RF signal without altering its amplitude. The multiple antenna 510-530 elements are coupled to the phase shifting components. The phase-shifting component is configured to control a direction and shape of the received signal in the phased-array system 500. In some embodiments, by adjusting the phase of the signal sent to each antenna element 510-530, the signals output from the antenna elements 510-530 can constructively interfere in one direction and destructively interfere in others, effectively steering the beam. Alternatively, in some embodiments, by applying the correct phase shifts to different antenna elements 510-530, the signal strength can be focused on a desired direction, which improves the gain and directivity of the antenna system 500.

Phased-array systems often involve a large number of antenna elements packed closely together to create a compact, highly directional antenna. The RF power dividers describe herein achieve this miniaturization by incorporating discrete inductors and/or capacitors that effectively perform the tasks of large traditional components, such as quarter-wave transmission lines, within a much smaller physical footprint. The benefit of using these discrete or lumped elements is twofold. Firstly, they allow the power divider to be integrated into systems where space is at a premium, such as compact phased-array antennas and portable RF communication devices. Secondly, the smaller size does not compromise the divider's functionality or efficiency at the desired frequency bands. This makes the RF power divider described herein particularly advantageous in modern electronic applications where performance and miniaturization are both important.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A radio frequency (RF) power divider comprising:
an input port, an internal node and two output ports;
a lumped element divider circuit connecting the internal node to the two output ports, the divider circuit comprising:
two branch circuits, each comprising an inductor connecting the internal node to one of the two output ports; and
an isolation circuit between the two output ports, the isolation circuit comprising a resistor; and
an impedance matching circuit connecting the input port to the internal node, the impedance matching circuit configured to selectively transmit or dissipate signal energy within a predetermined frequency band received from the input port.

2. The RF power divider of claim 1, wherein the impedance matching circuit includes a capacitor connecting the input port to the internal node, and a shunt inductor connecting the input port to ground.

3. The RF power divider of claim 2, wherein the input port receives an RF signal, and parameters of the capacitor and the shunt inductor are determined based on a frequency band of the RF signal.

4. The RF power divider of claim 1, wherein each branch circuit is a lumped element equivalent of a quarter-wave transmission line between the internal node and one of the output ports.

5. The RF power divider of claim 1, wherein the lumped element divider circuit further comprises: capacitors connecting the internal node to ground, and connecting each of the two output ports to ground.

6. The RF power divider of claim 1, wherein the lumped element divider circuit is a Wilkinson power divider.

7. The RF power divider of claim 1, wherein the input port and output ports are all matched to a same characteristic impedance, but an input impedance of the lumped element divider circuit is not matched to the characteristic impedance.

8. The RF power divider of claim 1, wherein the isolation circuit further comprises a capacitor in series with the resistor, forming a series R-C (resistor-capacitor) circuit between the two output ports.

9. The RF power divider of claim 8, wherein the input port receives an RF signal, and parameters of the series R-C circuit are determined based on a frequency band of the RF signal.

10. The RF power divider of claim 8, wherein the isolation circuit further includes a second resistor connected in parallel with the series R-C circuit between the two output ports.

11. The RF power divider of claim 10, wherein the input port receives an RF signal, and parameters of the second resistor is determined based on a frequency band of the RF signal.

12. A radio frequency (RF) system comprising one or more stages, each stage comprising one or more RF power dividers, each RF power divider comprising:
an input port, an internal node and multiple output ports;
a lumped element divider circuit connecting the internal node to the output ports, the divider circuit comprising:
branch circuits, each comprising an inductor connecting the internal node to one of the output ports; and
isolation circuits between the output ports, each isolation circuit comprising a resistor; and
an impedance matching circuit connecting the input port to the internal node, the impedance matching circuit configured to selectively transmit or dissipate signal energy within a predetermined frequency band received from the input port;
wherein, except for a last stage, output ports of each stage are connected to input ports of a next stage.

13. The RF system of claim 12, wherein the impedance matching circuit in a first stage includes a capacitor connecting the input port to the internal node, and a shunt inductor connecting the input port to ground.

14. The RF system of claim 13, wherein the input port receives an RF signal, and parameters of the capacitor and the shunt inductor are determined based on a frequency band of the RF signal.

15. The RF system of claim 13, wherein the isolation circuit further comprises a capacitor in series with the resistor, forming a series R-C (resistor-capacitor) circuit between the two output ports.

16. The RF system of claim 15, wherein the input port receives an RF signal, and parameters of the series R-C circuit are determined based on a frequency band of the RF signal.

17. A radio frequency (RF) power divider comprising:
a first node and two output ports;
a divider circuit connecting the first node to the two output ports, the divider circuit comprising:
two branch circuits, each comprising an inductor in series with a quarter-wave transmission line; and
an isolation circuit between the two output ports, the isolation circuit comprising a resistor.

18. The RF power divider of claim 17, further comprising:
an impedance matching circuit connecting an input port to the first node, the impedance matching circuit matching an input impedance of the divider circuit to a source impedance for the input port.

19. The RF power divider of claim 18, wherein the input port receives an RF signal, and parameters of the impedance matching circuit are further determined based on a frequency band of the RF signal.

20. A phased-array system, comprising:
an RF source that generates an RF source signal;
an RF system that splits the RF source signal into multiple lower power RF signals, the RF system comprising one or more stages, each stage comprising one or more RF power dividers, each RF power divider comprising:
an input port, an internal node and multiple output ports;
a lumped element divider circuit connecting the internal node to the output ports, the divider circuit comprising:
branch circuits, each comprising an inductor connecting the internal node to one of the output ports; and
isolation circuits between the output ports, each isolation circuit comprising a resistor; and
an impedance matching circuit connecting the input port to the internal node, the impedance matching circuit configured to selectively transmit or dissipate signal energy within a predetermined frequency band received from the input port;
wherein, except for a last stage, output ports of each stage are connected to input ports of a next stage;
a plurality of phase-shifting components coupled to the output ports of a last stage of the RF system, the phase-shifting components controllable to phase shift the multiple lower power RF signals; and
a plurality of antenna elements coupled to the phase-shifting components.
